(19) United States
(12) Patent Application Publication
(10) Pub. No.: US 2023/0297738 A1
(43) Pub. Date: Sep. 21, 2023

(54) SIMULATING PARTICLE DYNAMICS

(71) Applicant: NVIDIA Corporation, Santa Clara, CA (US)

(72) Inventor: Scott LEGRAND, Soquel, CA (US)

(21) Appl. No.: 17/654,972

(22) Filed: Mar. 15, 2022

(51) Int. Cl. G06F 30/25

(52) U.S. Cl. CPC G06F 30/25

(57) ABSTRACT

Embodiments of the present disclosure relate to a method of particle system analysis. The method may include during an analysis of behavior of multiple particles in a particle system, applying a scalar value, based on one or more parameters for the analysis, to a position value for one or more particles of the multiple particles. The method may further include determining, after applying the scalar value, a distance between a first particle of the multiple particles and a second particle of the multiple particles using the position values of the first particle and the second particle and converting the distance from a first value type to a different value type using the scalar value. The method may further include determining a behavior of the particle system based on the converted distance.

### BACKGROUND

The ability of processing systems, such as systems that include graphical processing units, to perform many mathematic computations has increased the ability to study many physical phenomena and assisted in the development of scientific research and new technologies. One particular area which has benefited greatly from the mathematic capabilities of processing systems is simulation of particle systems, such as the simulation of interactions between atoms at a molecular level. The simulation of interactions between atoms has assisted in technological fields ranging from drug discovery to material designs.

In particle system simulation, the fidelity of predictions hinges on the reliability and accuracy of the computations performed to simulate the interactions of the particles. Changes in the reliability and accuracy of the computations may result in failed simulations or inaccurate results.

### SUMMARY

Embodiments of the present disclosure relate to particle system analysis, particularly (though without limitation) to simulations of particle systems and applications. One or more embodiments may be implemented as a method for analyzing the behavior of particles in a particle system that includes applying a scalar value to a position value for one or more particles of the multiple particles. The scalar value may be based on parameters for the analysis. One or more implementations of the method may further include, determining, after applying the scalar value, a distance between a first particle of the multiple particles and a second particle of the multiple particles using the position values of the first particle and the second particle and converting the distance from a first value type to a different value type using the scalar value. One or more implementations of the method may further include determining a behavior of the particle system based on the converted distance.

### BRIEF DESCRIPTION OF THE DRAWINGS

The present systems and methods for yield scenario encoding for autonomous systems are described in detail below with reference to the attached drawing figures, wherein:

FIG. 1 illustrates an example simulation environment configured to simulate behavior of particle systems, in accordance with some embodiments of the present disclosure;

FIG. 2 is a flow diagram showing an example method for analyzing behavior of a particle system, in accordance with some embodiments of the present disclosure;

FIG. 3 illustrates an example particle diagram, in accordance with some embodiments of the present disclosure;

FIG. 4 illustrates a diagram with a particle system in relation to a coordinate system, in accordance with some embodiments of the present disclosure;

FIG. 5 illustrates a configuration of cells into which particles of a particle system are partitioned, in accordance with some embodiments of the present disclosure;

FIG. 6 is a flow diagram showing an example portion of a method for analyzing behavior of a particle system, in accordance with some embodiments of the present disclosure;

FIG. 7 is a flow diagram showing another example portion of a method for analyzing behavior of a particle system, in accordance with some embodiments of the present disclosure;

FIG. 8 is a flow diagram showing another example method for analyzing behavior of a particle system, in accordance with some embodiments of the present disclosure;

FIG. 9 is a flow diagram showing another example method for analyzing behavior of a particle system, in accordance with some embodiments of the present disclosure;

FIG. 10 is a block diagram of an example computing device suitable for use in implementing some embodiments of the present disclosure; and

FIG. 11 is a block diagram of an example data center suitable for use in implementing some embodiments of the present disclosure.

### DETAILED DESCRIPTION

A particle system, such as a molecular compound, may be simulated to understand how the system behaves over time. In particular, the simulation of particle systems may provide an indication of how the system reacts over time in response to interactions between the individual particles. In some circumstances, a particle system may include thousands, tens of thousands, or hundreds of thousands of particles, such as atoms. As a result, a simulation of the system may consider hundreds of thousands or millions of calculations per simulation iteration.

To maintain accuracy of a simulation, data regarding the particles, such as a particle location within the system, may be stored using a first value type of a first number of bits. However, based on a design of processing units performing calculations for the simulation, the processing units may operate more efficiently when processing data of a second value type of a second number of bits that is less than the first number of bits. In these and other circumstances, the data may be converted to the second value type during simulation when making calculations to increase the efficiency of the simulation. However, roundoff errors may occur when converting between value types. The roundoff errors may result in inaccuracies in the simulation. For example, a positive roundoff error may cause a system during simulation to lose energy and a negative roundoff error may cause a system during simulation to gain energy.

According to one or more embodiments of the present disclosure, to reduce potential inaccuracies in the simulation due to converting between value types, values used for the simulation may be converted to a third value type. In some embodiments, the third value type may have a mantissa with more bits than a mantissa of the second value type. Alternately or additionally, a scalar, based on simulation parameters applied during the simulation, may be applied to a value of the first value type before converting to the value to the third value type. The value in the third value type may be stored and used during the simulation. During the simulation, the value of the third value type may also be converted to the second value type. When converting the value to the second value type from the third value type, the scalar value may again be used. As an example, the values used for the simulation may be locations of particles in the system. In these and other embodiments, distances between particles may be calculated based on the values of the locations of the particles. The simulation may determine a behavior of the particle system based on the distances between the particles.

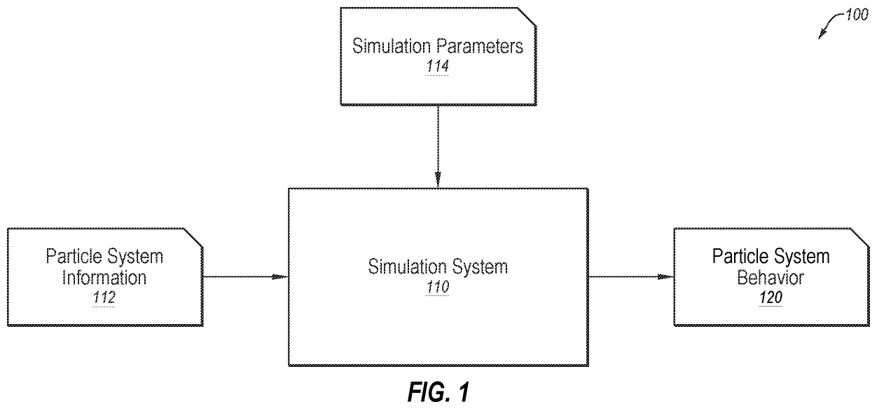

With reference to FIG. 1, FIG. 1 illustrates an example simulation environment 100 configured to simulate behavior of particle systems. The simulation environment 100 may be implemented according to one or more embodiments of the present disclosure. The simulation environment 100 may include a simulation system 110 that may obtain particle system information 112 of a particle system and simulation parameters 114. The simulation system 110 may output a particle system behavior 120 based on the obtained particle system information 112 and the simulation parameters 114.

In some embodiments, the simulation system 110 may include code and routines configured to enable a computing system to perform one or more operations. Additionally or alternatively, the simulation system 110 may be implemented using hardware including one or more processors, graphical processing units (GPUs), data processing units (DPUs), microprocessors (e.g., to perform or control performance of one or more operations), field-programmable gate arrays (FPGA), and/or application-specific integrated circuits (ASICs). In some other instances, the simulation system 110 may be implemented using a combination of hardware and software. In the present disclosure, operations described as being performed by the simulation system 110 may include operations that the simulation system 110 may direct a corresponding system to perform.

In some embodiments, the particle system information 112 may include information regarding a particle system. The particle system may include multiple different particles. In some embodiments, some of the particles in the particle system may be bonded together. For example, the particle system may be a compound molecule. In these and other embodiments, the compound molecule may include multiple atoms. Some of the atoms may be bonded together, such as by a covalent or ionic bond. These particles bonded together may be referred to as bonded particles. Alternately or additionally, some of the particles in the particle system may not be directly bonded to other particles or through a common particle but positioned such that the particles may cause an effect on other particles in the particle system. When discussing the effects of separated particles on each other, the particles may be referred to as nonbonded particles. Note that a first particle may be bonded with a second particle and also be nonbonded with a third particle.

In some embodiments, the particle system information 112 may further include information about the particles, such as a type of the particle, a location of the particle within the particle system, energy levels of the particle, among other information about the particles.

In some embodiments, the simulation parameters 114 may define how the simulation system 110 may perform a simulation of the particle system. The simulation parameters 114 may include one or more of a distance within which to consider effects between nonbonded particles, a dielectric constant, a heating phase time, a time step size, data value types, and a simulation run time, among others. The simulation parameters 114 may affect how the simulation system 110 determines the particle system behavior 120.

In some embodiments, the simulation system 110 may obtain the particle system information 112 and the simulation parameters 114 and may be configured to perform simulations to determine interactions between the particles to analyze a behavior of the particle system. The simulation system 110 may output the particle system behavior 120 based on the simulations.

In some embodiments, the simulation system 110 may simulate the behavior of the particle system by iteratively calculating energy between the particles in the particle system and analyzing how the energy between the particle system changes over time and how the change in energy effects the particle systems, such as locations of the particles and bonds between the particles. For example, in some embodiments, the simulation system 110 may consider stretching, bonding, and torsional energy between bonded particles and vanderWaals, electrostatic, and improper energies between nonbonded particles. In these and other embodiments, a distance between nonbonded particles may be used to determine the vanderWaals and electrostatic energies. As such, during the simulation of the particle system, the simulation system 110 may calculate distances between nonbonded particles so that vanderWaals and electrostatic energies between nonbonded particles may be calculated.

In some embodiments, the simulation system 110 may consider vanderWaals and electrostatic energies between particles that are positioned within a distance such that the vanderWaals and electrostatic energies are significant enough to be considered in the simulation. For example, each of the vanderWaals and electrostatic energies are dependent on distances between particles such that as the distance between particles increases, the vanderWaals and electrostatic energies between the particles decreases. Thus, at distances more than an interaction distance, the vanderWaals and electrostatic energies may be at such a magnitude that the energies may not be considered by the simulation system 110. The interaction distance may be selected for the simulation system 110 in the simulation parameters 114.

In some embodiments, distances between nonbonded particles are calculated based on the locations of the particles in the particle system. The locations of the particles may be stored using a first value type. Based on a configuration of the computing system on which the simulation system 110 is hosted, in some circumstances, the computer system may more efficiently perform calculations using a second value type. In these and other embodiments, the second value type may include fewer bits than the first value type. For example, the first value type may be a 64-bit floating point and the second value type may be a 32-bit floating point. Alternately or additionally, the first value type may be a 32-bit floating point and the second value type may be a 16-bit floating point.

In these and other embodiments, the simulation system 110 may truncate the values of the locations of the particles from the length of the first value type to the length of the second value type. After truncating the values of the locations, the values of the locations may be stored and distances between particles may be determined based on the stored values.

In some embodiments, to reduce a magnitude of the values of the locations that are stored, the particle system may be partitioned into cells. Each cell may include an origin and the locations of the particles with respect to the origin of the entire particle system may be translated to be with respect to the origin of the cell that includes the particle. In these and other embodiments, an origin of a cell may be referred to as a local origin and an origin of the particle system may be referred to as a global origin.

In these and other embodiments, the cells may include dimensions that are based on the interaction distance. Because the dimensions of the cells are based on the interaction distance, all particles within the interaction distance of a particular particle are in a current cell of the particular particle or a cell directly adjacent to the current cell. As a result, the values of the locations of particles with respect to the local origin of the cells are smaller in magnitude than the values of the locations of particles with respect to the global origin of the particle system. In some embodiments, performing calculations on values with lower magnitudes may reduce computational errors due to rounding when values are stored in data types with finite representations of values. A reduction in computational errors may reduce noise in the simulation.

In some embodiments, to further reduce computational errors due to rounding, the values of the locations of the particles with respect to local origins may be stored in a third value type with a mantissa that is larger than the second value type. A larger mantissa may allow for more significant digits of the locations of the particles to be stored, thereby further reducing computational errors due to rounding. For example, the third value type may be an integer value type with a mantissa of 31 bits and the second value type may be a floating point with a mantissa of 23 bits. Thus, in some embodiments, a location of a particular particle may be truncated and converted from a first value type to a third value type for storage. Furthermore, data regarding distances sizing of the cells that may be used to calculate distances between particles in adjacent cells may be stored using the third value type. In these and other embodiments, when calculating distances between particles in adjacent cells, the location of the particles and the sizing of the cells may be used for at least some of the calculations when the values have the third value type.

In some embodiments, for some calculations during the simulation, the location of the particular particle may be converted to the second value type for more efficiently calculation performance. Alternately or additionally, calculations for determining the difference between the locations of particles may be performed using values in the third value type. In these and other embodiments, adjustments may be made to the process to assist in more efficient computation of the differences.

In some embodiments, the adjustments to the process may include grouping the particles into groups of equal size. Calculations for particles in a group may be performed in overlapping time periods, such as at the same time. For example, in these and other embodiments, the calculations for each of the particles in the group may be performed by a thread of a multi-thread processing unit. As such, each thread may be processed in overlapping periods of time.

In these and other embodiments, however, due to the number of particles potentially not being divisible by the size of the groups, some particles may remain after forming the groups. To avoid have special instructions for a processing unit to handle the remaining particles, a group may be formed with placeholder particles and the remaining particles. As a result, the processing unit may process all the particles in a similar manner. To avoid introducing errors into a simulation by the introduction of placeholder particles, the placeholder particles may be positioned in the system such that the placeholder particles are greater than the interaction distance from particles being considered such that no calculations are performed for the placeholder particles and the placeholder particles are essential ignored during the calculations performed by the processing unit.

In some embodiments, before converting a value type of the positions of the particles to a third value type, a scalar value may be applied to the positions of the particles. Applying the scalar value may assist in bounding the dynamic range of the positions when converting the positions to the third value type. In these and other embodiments, the scalar value may be based on the interaction distance. In these and other embodiments, an inverse of the scalar value may be applied to the values of the positions of the particles before converting the positions of the particles to the second value type or the first value type to remove the scalar value.

In some embodiments, the particle system behavior 120 output by the simulation system 110 may indicate how the locations, energies, and/or bonds between the particles in the particle system may change overtime based on interactions between the particles in the particle system.

Modifications, additions, or omissions may be made to FIG. 1 without departing from the scope of the present disclosure. For example in some embodiments, the simulation system 110 may include addition input parameters than those considered such as information regarding the computing system on which the simulation system 110 is hosted.

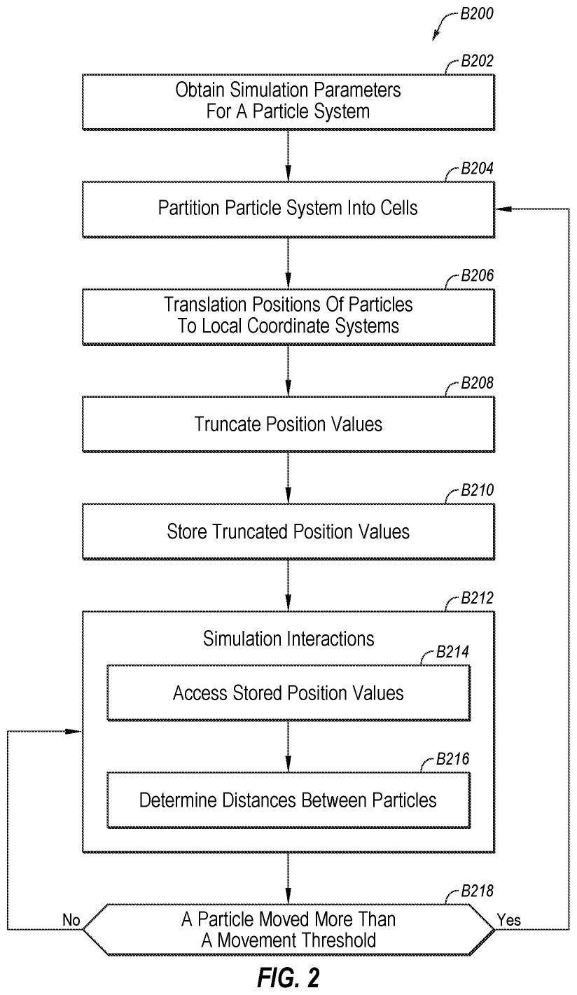

Now referring to FIG. 2, each block of method 200, and other methods described herein, comprises a computing process that may be performed using any combination of hardware, firmware, and/or software. For instance, various functions may be carried out by a processor executing instructions stored in memory. The methods may also be embodied as computer-usable instructions stored on computer storage media. The methods may be provided by a standalone application, a service or hosted service (standalone or in combination with another hosted service), or a plug-in to another product, to name a few. In addition, method 200 is described, by way of example, with respect to the simulation system 110 of FIG. 1. However, these methods may additionally or alternatively be executed by any one system, or any combination of systems, including, but not limited to, those described herein.

FIG. 2 is a flow diagram showing an example method 200 for analyzing behavior of a particle system, in accordance with some embodiments of the present disclosure. The method 200 may be carried out via a simulation system, such as but not limited to the simulation system 110 of FIG. 1.

The method 200, at block B202, includes obtaining one or more simulation parameters for a particle system. The simulation parameters may include parameters such as the simulation parameters 114 of FIG. 1. The simulation parameters may be parameters used by a simulation system, such as the simulation system 110 of FIG. 1 to simulate behavior of a particle system. Some of the simulation parameters may be based on a configuration of the particle system. Some of the simulation parameters may be based on a desired accuracy of the simulation, run time of the simulation, and/or processing system used to perform the simulation, among other elements of a simulation.

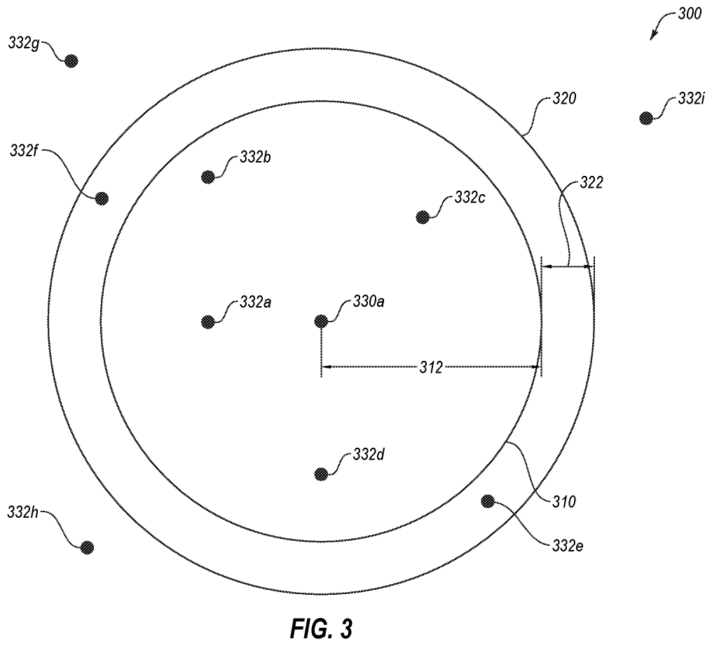

In some embodiments, a simulation parameter may include an interaction distance for considering interactions between particles. Alternately or additionally, a simulation parameter may include a particle movement distance. Both the interaction distance and particle movement distance are further described with respect to FIG. 3.

At block B204, the particle system may be partitioned into one or more cells. In some embodiments, the cells may be a three-dimensional rectangular cuboid. A length of each side of a cell may be at least a length of a combination of the interaction distance and the particle movement distance. In some embodiments, the length of each side of a cell may vary during a simulation in response to a change to one or more of the interaction distance and the particle movement distance.

In some embodiments, the particle system may be partitioned into a sufficient quantity of cells such that one or more of the particles in the particle system are located within a cell. Based on the distribution of particles in the particle system, the cells may have a distribution greater in one dimension than another dimension.

In some embodiments, one or more of the cells may include a local origin as a reference point for a local coordinate system within each of the cells. The local origin may be a reference point within the cells, but a location for the local origin for one or more of the cells may be the position within each cell. For example, the local origin may be in the same corner of each cell.

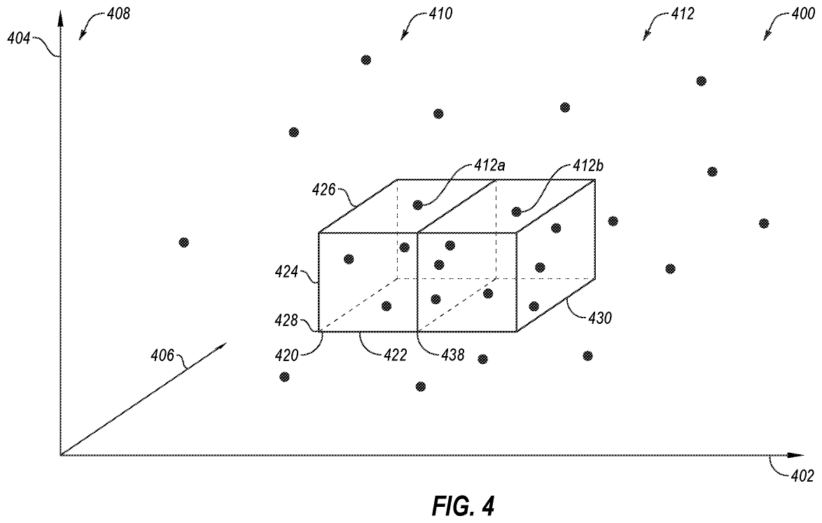

In some embodiments, a location of each particle within a first cell may be determined with respect to a local origin of the first cell in a local coordinate system. Alternately or additionally, a location for each particle within cells directly adjacent to a first cell may be determined with respect to the local origin and the local coordinate system of the first cell. For example, a first particle in the first cell may have a first location with respect to a first origin of the first cell. A second particle in a second cell may have a second location with respect to a second origin of the second cell. A distance between the first origin and the second origin may be determined based on the size of the first and second cells and the locations of the first origin and the second origin. As such, a location of the second particle with respect to the first origin may be the second location offset by the distance between the first origin and the second origin. Thus, a distance between the first particle and the second particle may be determined with respect to the local coordinate system of the first cell even though the second particle is not located in the first cell and the position of the second particle is not part of the local coordinate system of the first cell. FIG. 4 provides an example illustration of some cells in a particle system. In these and other embodiments, a first cell may be considered directly adjacent to a second cell when the first cell and the second cell touch at a cell boundary.

At block B206, one or more positions of particles in a global coordinate system may be translated to a local coordinate system. The local coordinate system may be a coordinate system of the cells that include the particles. The position a first particle in the global coordinate system may be translated to a local coordinate system of a first cell based on the position of the first cell within the global coordinate system. For example, a position of an origin of the local coordinate system of the first cell in the global coordinate system may be determined. To map the position of the first particle to the local coordinate system of a cell, the position of the local origin of the cell in the global coordinate system may be removed from the position of the first particle in the global coordinate system. As a result, the location of the first particle in the local coordinate system may be the difference between the position of the local origin in the global coordinate system and the position of the first particle in the global coordinate system.

In some embodiments, the position for a particle in a local coordinate system with respect to each dimension in a three-dimensional space may be determined separately. Alternately or additionally, in some embodiments, the position of a particle in the global coordinate system may be normalized before determining the difference between the position of the local origin in the global coordinate system and the position of the first particle in the global coordinate system. For example normalizing the position of a particle in the global coordinate system may include mapping the position of the particle to a known global origin. The position of a particle in the global coordinate system may be mapped to a known global origin using a modulus operator with respect to size of all cells. The following equation may illustrate translation from a global coordinate system to a local coordinate system for the x dimension:

XLocalPosition=(XGlobalPosition% XGridsize)−(XCellNumber*XCellSize)

where XLocalPosition is the position in the x dimension of a particle in the local coordinate system, XGlobalPosition is the position in the x dimension of a particle in the global coordinate system, XGridsize is the size of a cells in the x dimension, XCellNumber is a number of a cell that includes the particle, and XCellSize is the size of one cell in the x dimension. In these and other embodiments, the product of XCellNumber and XCellSize provides the location of the local origin of the cell in the x dimension of the global coordinate system and XGlobalPosition modules XGridsize provides a normalized value of the position of the particle in the global coordinate system. As illustrated, a similar equation may be performed for the y dimension and the z dimension so that the position of the particle is known in all three dimensions. In these and other embodiments, the values for the positions used in this step may have a first value type.

At block B208, the position values of one or more particles in the local coordinate system may be truncated. Truncation of the position values may convert the position values to a third value type. In these and other embodiments, the number of bits in the third value type may be less than the number of bits in the first value type. For example, the first value type may use 64 bits and the third value type may use 32 bits. Alternately or additionally, the first value type may be of a different format than the third value type. For example, the first value type may be a floating-point format and the third value type may be an integer format.

In some embodiments, before truncating the position value a scalar value may be applied to the position values. In these and other embodiments, the scalar value may be applied based on changing formats from the first value type to the third value type. The scalar value may assist to bound a dynamic range of the value that is stored in the third value type.

In some embodiments, the scalar value may be based on the dimensions of the cells. For example, the scalar value may be based on values of the interaction distance and/or the particle movement distance. For example, a scalar value may be calculated as follows:

Scalar=(2\hat{ }bitsize)/((1.5*(C+S))+(0.5*S)+EM)

where bitsize is the number of bits of the mantissa of the third value type, C is the interaction distance, S is the particle movement distance, and EM is an error margin based on rounding errors that may occur when adding values with a computer using data types with a limited mantissa. In some embodiments, the scalar value may also be applied to an offset distance that represents a distance between origins of adjacent cells.

At block B210, truncated position values of the particles may be stored. The position values may be stored in memory for use during a simulation. The position values may be stored in the third value type. For example, the position values may be calculated, stored, and then accessed during iterations of the simulation.

At block B212, one or more interactions between particles may be simulated. Simulations of the interactions between particles may allow for an analysis of the behavior of the particle system over time. The simulation may consider bonded and non-bonded interactions between particles. In some embodiments, when simulating non-bonded interactions between particles, the simulation may perform the actions recited in blocks B214 and B216.

At block B214, stored position values may be accessed from memory. The stored position values may be accessed in the third value type. The stored position values may be accessed when a distance between particles is calculated during the simulation.

At block B216, distances between particles may be determined based on the stored position values. The distances may be used to determine interactions between the particles which may be used to determine a behavior of the particle system.

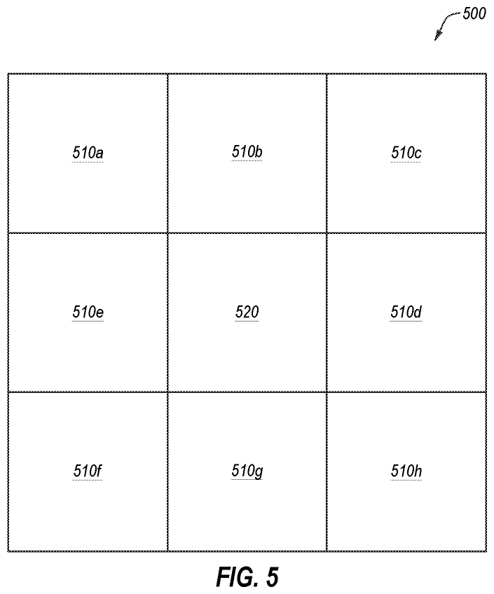

In some embodiments, as described previously, only interactions between particles that are within the interaction distance may be considered by a simulation. Thus, for the simulation, the interactions between each particle and all the particles within the interaction distance for each particle may be considered. In these and other embodiments, particles may be determined to potentially be within the interaction distance of a particular particle based on the cell of the particular particle. For example, all of the particles within the cell of the particular particle may potentially be within the interaction distance. Furthermore, all particles within directly adjacent cells of the cell of the particular particle may potentially be within the interaction distance of the particular particle. Thus, during a simulation the distances between each particle in a cell, the other particles in the cell, and the particles in all directly adjacent cells may be calculated. Interactions may be determined for those particles with a distance therebetween less than the interaction distance. Further description of calculating distances between particles in adjacent cells is discussed with respect to FIG. 5.

In some embodiments, to calculate a distance between a first particle in a first cell and a second particle in a second cell adjacent the first cell, the location of the second particle with respect to a first origin of the first cell may be determined. The location of the second particle with respect to the origin of the first cell may be a location of the second particle with respect to a second origin of the second cell offset by the distance between the first origin and the second origin. The distances between origins of cells may be referred to as cell offsets.

In some embodiments, the stored position values may be accessed in the third value type. In these and other embodiments, the cell offsets may have been stored in the third value type and may be accessed in the third value type. Thus, when determining a location of the second particle, the location may be a sum of the stored position value of the second particle in the third value type with a corresponding cell offset stored in the third value type.

In some embodiments, during the simulation, values that result from calculations involving values of the third value type may be converted to a second value type. The second value type may be of the same format as the first value type. In these and other embodiments, the second value type may have a length equal to the length of the third value type. However, the second value type may have a mantissa that is shorter in length than the mantissa of the third value type.

In some embodiments, one behavior of the particle system may include movement of particles. Thus, during iterations of simulation, positions of particles may be updated. As positions of the particles are updated, the particles may move such that a particle previously located in one cell is now located in another cell. As a result, after one or more iterations of a simulation, a cell assignment of a particle may be incorrect. An incorrect cell assignment may result in an interaction between two particles not being considered when the interaction should be considered, or an interaction being considered when the interaction should not be considered. In these instances, the particle system may be repartitioned into cells.

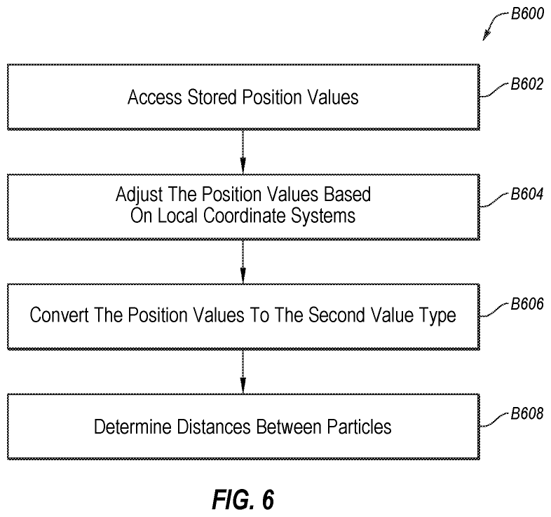

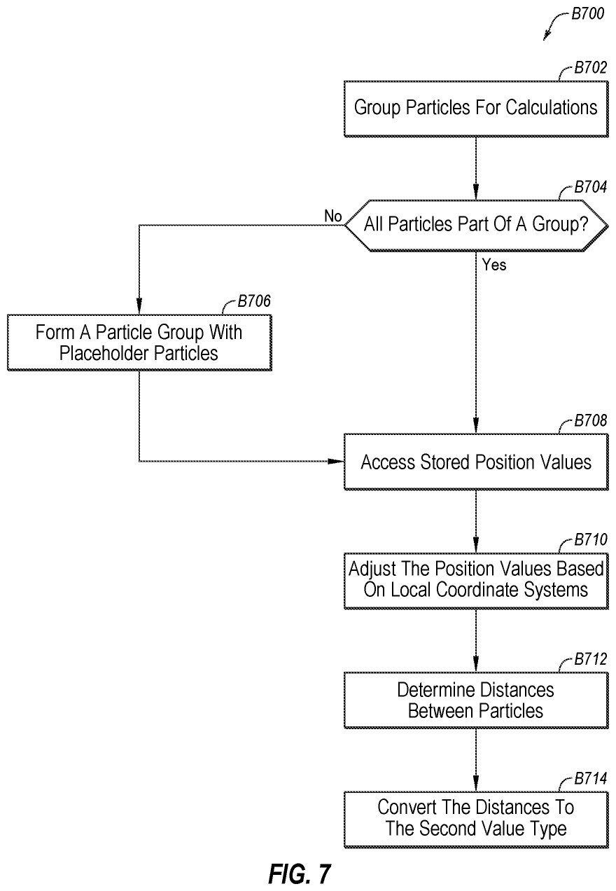

In some embodiments, the repartitioning of the cells may occur in response to movement of the particles. In some embodiments, any movement of particles may be considered for repartitioning of the cells. Alternately or additionally, movement of particles that may be more than a movement threshold may be considered for repartitioning of the cells. In these and other embodiments, the movement threshold may be based on the interaction distance and/or the particle movement distance. For example, the movement threshold may be a portion of the interaction distance and/or the particle movement distance. As an example, the movement threshold may be half of the particle movement distance. Additional description of actions performed when simulating non-bonded interactions between particles is described with respect to FIGS. 6 and 7.

At block B218, it may be determined if a particle moved more than the movement threshold. In response to a particle moving more than the movement threshold, the method 200 may proceed to B204. At B204, the particle system may be repartitioned into cells and the method 200 may proceed as described above to again translate position values of particles, truncate the position values, and store them. In response to a particle not moving more than the movement threshold, the method 200 may continue to simulate interactions between the particles.

Modifications, additions, or omissions may be made to the method 200 without departing from the scope of the present disclosure. For example, the functions and/or operations performed may be implemented in differing order. Furthermore, the outlined functions and operations are only provided as examples, and some of the functions and operations may be optional, combined into fewer functions and operations, or expanded into additional functions and operations without detracting from the essence of the disclosed embodiments. In some embodiments, the method 200 may include additional blocks or fewer blocks.

FIG. 3 illustrates an example particle diagram 300, in accordance with some embodiments of the present disclosure. The particle diagram 300 may illustrate multiple particles from a particle system including a primary particle 330 and secondary particles 332a-332i.

In some embodiments, during a simulation of the behavior of the primary particle 330 and the secondary particles 332a-332i, interactions between non-bonded particles may be considered. However, as discussed above, with respect to a particular particle, such as the primary particle 330, only interactions with particles that are within an interaction distance of the particular particle may be considered. FIG. 3 illustrates the particles with which interactions are considered with respect to the primary particle 330.

In some embodiments, a particle interaction boundary 310 with a radius 312 may be selected for the primary particle 330. The particle interaction boundary 310 may form an enclosure around the primary particle 330. Interactions between the primary particle 330 and the particles of the secondary particles 332a-332i that are within the particle interaction boundary 310 may be used during a simulation. Thus, during a simulation of the particle system, the simulation may use the interactions between the primary particle 330 and each of the particles within the particle interaction boundary 310, namely the secondary particles 332a-332d. A simulation may determine which interactions with the secondary particles 332a-332i to include based on distances between the secondary particles 332a-332i and the primary particle 330. In these and other embodiments, when a distance between the primary particle 330 and one of the secondary particles 332a-332i is less than the radius 312, the interactions between the one of the secondary particles 332a-332i and the primary particle 330 is considered. In these and other embodiments, a length of the radius 312 may be based on a simulation parameter, such as the interaction distance. The magnitude of the radius 312 may be based on a type of the particle system and/or a desired accuracy, tolerance, or other aspect of a simulation. In FIG. 3, the particle interaction boundary 310 is illustrated in two-dimensions as a circle, however, in implementation, the particle interaction boundary 310 may be a sphere with the radius 312 extending in all directions away from the primary particle 330.

During simulation of the particle system, the particles may move. Thus, during a simulation a particle close to the particle interaction boundary 310 may move to be within the particle interaction boundary 310. For example, the secondary particles 332f may move to be within the particle interaction boundary 310. Thus, in some embodiments, a simulation may further consider particles within a particle consideration boundary 320 as candidate particulars for which interactions with the primary particle 330 may be used. The particle consideration boundary 320 may include a thickness 322. In some embodiments, the thickness 322 may be a simulation parameter, such as a particle movement distance. A magnitude of the thickness 322 may be based on a type of the particle system and/or a desired accuracy, tolerance, or other aspect of a simulation.

In these and other embodiments, during every iteration of a simulation, the distances between the primary particle 330 and other particles within the particle consideration boundary 320 may be determined. However, only interactions between those particles with distances to the primary particle 330 that are less than the radius 312 may be used during the simulation. As such, during an iteration of a simulation, distances between the secondary particles 332a-332f and the primary particle 330 may be determined, but only those interactions between the primary particle 330 and the secondary particles 332a-332d within the particle interaction boundary 310 may be used.

As illustrated in FIG. 3, interactions between the primary particle 330 and the secondary particles 332e-332i may not be considered in one or more embodiments. However, as the particles move over time, one or more of the particles with which interactions with the primary particle 330 may be considered may change. For example, the secondary particle 332b may move outside the particle interaction boundary 310 and the secondary particle 332f may move inside the particle interaction boundary 310.

Additionally, note that a magnitude of the radius 312 and a magnitude of the thickness 322, and thus the magnitude of the simulation parameters of the interaction distance and the particle movement distance, may be a function of a parameter in the simulation. For example, in some embodiments, the magnitude of the radius 312 and the magnitude of the thickness 322 may be a function of a pressure within the simulation. Thus, the magnitude of the radius 312 and the magnitude of the thickness 322 may be initialized for a simulation. As a pressure varies during the simulation, the magnitude of the radius 312 and the magnitude of the thickness 322 may vary. For example, as the pressure increases the magnitude of the radius 312 and the magnitude of the thickness 322 may decrease and as the pressure decreases the magnitude of the radius 312 and the magnitude of the thickness 322 may increase.

Furthermore, note that each particle of a particle system may include a particle interaction boundary 310 and a particle consideration boundary 320 even though FIG. 3 only illustrates the particle interaction boundary 310 and the particle consideration boundary 320 for the primary particle 330.

Modifications, additions, or omissions may be made to FIG. 3 without departing from the scope of the present disclosure. For example, in some embodiments, the particle consideration boundary 320 may not be considered. In these and other embodiments, after every iteration of a simulation, particles that are within a particle interaction boundary 310 of each particle may be determined. By using the particle consideration boundary 320, only after a particle moves more than half the distance of the thickness 322 would the particles within the particle consideration boundary 320 be redetermined.

FIG. 4 illustrates a diagram 400 with a particle system 410 in relation to a coordinate system 408, in accordance with some embodiments of the present disclosure. The particle system 410 includes particles 412 and the coordinate system 408 includes an x-axis 402, a y-axis 404, and a z-axis 406.

The diagram 400 further illustrates a first cell 420 and a second cell 430 within the particle system 410. The first cell 420 may include a first side 422, a second side 424, a third side 426, and a first origin 428. The first side 422 may be aligned with the x-axis 402, the second side 424 may be aligned with the y-axis 404, and the third side 426 may be aligned with the z-axis 406. Each of the first side 422, the second side 424, and the third side 426 may have a length that is as long as or longer than a combination of an interaction distance and a particle movement distance. Note that each of the first side 422, the second side 424, and the third side 426 may have different lengths or the same lengths. The first origin 428 may be positioned at the lower left-hand corner. Similarly, a second origin 438 of the second cell 430 may be positioned at the lower left-hand corner of the second cell 430.

In some embodiments, both the first cell 420 and the second cell 430 may encompass some of the particles 412 of the particle system 410. For example, the first cell 420 may encompass a first particle 412a and the second cell 430 may encompass a second particle 412b. In these and other embodiments, the first particle 412a may include a global location with respect to a global origin in a global coordinate system for the particle system 410. The first particle 412a may further include a local location with respect to the first origin 428 in a first local coordinate system of the first cell 420. For example, the location of the first particle 412a may include x component, a y component, and a z component. The x component may be a distance of the first particle 412a along the x-axis 402 from the first origin 428. The y component may be a distance of the first particle 412a along the y-axis 404 from the first origin 428. The z component may be a distance of the first particle 412a along the z-axis 406 from the first origin 428.

In some embodiments, the second particle 412b may also include a local location with respect to the second origin 438 in a second local coordinate system of the second cell 430. A position of the second particle 412b with respect to the first origin 428 and the first local coordinate system of the first cell 420 may be determined based on a spatial relationship between the first origin 428 and the second origin 438. For example, the second origin 438 may offset from the first origin 428 along the x-axis 402. As such, the second local coordinate system is offset from the first local coordinate system the distance between the first origin 428 and the second origin 438 along the x-axis 402. Thus, the location of the second particle 412b in the second local coordinate system may be translated to a location in the first local coordinate system by adding the offset between the first origin 428 and the second origin 438 along the x-axis 402.

For example, a location of the second particle 412b may be (3, 4, 3) in the second local coordinate system and the offset between the first origin 428 and the second origin 438 may be 6 in the x dimension. As such, the location of the second particle 412b may be (9, 4, 3) in the first local coordinate system. As a result, a distance between the first particle 412a and the second particle 412b may be determined with respect to the first local coordinate system.

Modifications, additions, or omissions may be made to FIG. 4 without departing from the scope of the present disclosure. For example, FIG. 4 only illustrates two cells for ease in explanation. During a simulation, cells may be constructed to encompass all of the particles 412 of the particle system 410.

FIG. 5 illustrates a configuration of cells 500 into which one or more particles of a particle system are partitioned, in accordance with some embodiments of the present disclosure. The configuration of cells 500 may include a primary cell 520 and secondary cells 510a-510h. As illustrated, the secondary cells 510a-510h may be directly adjacent to the primary cell 520. For example, each of the secondary cells 510a-510h may touch a boundary of the primary cell 520.

The configuration of cells 500 is illustrated in two-dimensions. Thus, the configuration of cells 500 would extend either into or out of the page. In addition, in three-dimensions, additional cells would surround the primary cell 520. For example, a first set of nine cells would be positioned in front of the cells illustrated and a second set of nine cells would be positioned in back of the cells illustrated. The first and second set of nine cells may be referred to as secondary third-dimension cells.

As described previously, only interactions between particles that are within an interaction distance may be considered by a simulation. Thus, for the simulation, the interactions between each particle and all the particles within the interaction distance for each particle may be considered. In these and other embodiments, particles may be determined to potentially be within the interaction distance of a particular particle based on the cell of the particular particle. For example, when the particular particle is located in the primary cell 520, the cells within the interaction distance of the particular particle may include the secondary cells 510a-510h in two dimensions. In three dimensions, the cells within the interaction distance of the particular particle may include the secondary cells 510a-510h and the secondary third-dimension cells. Thus, in three dimensions the particles in twenty-six cells adjacent to the primary cell 520 may be considered as within the interaction distance of the particular particle in the primary cell 520. Note that the dimension of each of the cells may be the sum of the interaction distance and the particle movement distance. Thus, which particles in the other cells are within the interaction distance of the particular particle may depend on the location of the particular particle in the primary cell 520 and the location of the particles in the other cells. However, the arrangement of particles in cells allows a system to determine candidate particles for interactions with a particular particle.

Note that if each particle in each cell is considered with respect to each particle of either other cell, then the distance between two particles may be determined twice. For example, during simulation, each of the secondary cells 510a-510h may be considered as a primary cell. Thus, when the secondary cell 510g is considered the primary cell, the distance between particles in the secondary cell 510g and the primary cell 520 may be determined. However, when the distances are determined between particles in the primary cell 520 and other cells, the distances between the particles in the primary cell 520 and the secondary cell 510g may again be determined. In these and other embodiments, a distance between two particles may not need to be determined twice. Thus, once distances between particles in different cells are determined, the distance may be not redetermined.

In some embodiments, to avoid determining distances between two particles twice, when distances are determined with respect to particles of a given cell, only those cells that contain particles with which distances between those cells and the given cell have not been determined may be calculated. For example, when distances between particles with respect to the particles of the secondary cell 510f are determined, the distances between the particles in the primary cell 520 and the particles in the secondary cell 510f may be determined. As such, when distances between particles with respect to the particles of the primary cell 520 are determined, the particles of the secondary cell 510f are not considered. In these and other embodiments, based on the configuration of cells 500, when distances between particles with respect to the particles of the primary cell 520 are determined only the particles in the secondary cells 510a-d may be considered because the distances between particles in the secondary cells 510e-h and the particles in the primary cell 520 may have already been determined. Thus, in two-dimensions, distances between particles in four cells may be determined with respect to a given cell. In three-dimensions, distances between particles in thirteen cells may be determined with respect to a given cell. By only considering a subset of adjacent cells when making distance between particle determinations, duplication of distance between particle determinations may be avoided.

Modifications, additions, or omissions may be made to FIG. 5 without departing from the scope of the present disclosure. For example, the dimensions of the cells may be different than those illustrated.

FIG. 6 is a flow diagram showing an example portion of a method 600 for analyzing behavior of a particle system, in accordance with some embodiments of the present disclosure. The method may be carried out via a simulation system, such as but not limited to the simulation system 110 of FIG. 1.

The method 600, at block B602, includes accessing one or more stored position values from memory. The stored position values may be accessed in the third value type. The stored position values may be accessed when a distance between particles is calculated during a simulation. A cell may be selected for determining distances between particles in a given cell and particles in adjacent cells. The position values of the particles in the given cell and the particles in the adjacent cells may be accessed.

At block B604, the position values of the particles in the adjacent cells may be adjusted based on the local coordinate systems of the adjacent cells. In these and other embodiments, cell offsets based on the distances between the given cell and the adjacent cells may also be accessed. The cell offsets may be accessed in the third value type. The cell offsets may be applied to the position values of the particles in the adjacent cells to obtain the locations of the particles in the adjacent cells in the local coordinate system of the given cell.

At block B606, the position values of one or more of the particles may be converted to the second value type. After converting the position values of the one or more particles, the scalar value applied to both the position values of the particles and the cell offsets before being stored in memory may be removed. For example, an inverse of the scalar value may be applied to the position values of the particles and the cell offsets.

At block B608, distances between particles may be determined based on the position values of the particles in the second value type. In these and other embodiments, a difference between the position values in the second value type may be calculated. The distances may be compared to the interaction distance. In response to a distance being less than or equal to the interaction distance, an interaction between particles may be considered by the simulation. In these and other embodiments, the interaction may be a nonbonded interaction that may be based on the distance. In response to a distance being more than the interaction distance, no interaction between particles may be considered by the simulation.

Modifications, additions, or omissions may be made to the method 600 without departing from the scope of the present disclosure. For example, the functions and/or operations performed may be implemented in differing order. Furthermore, the outlined functions and operations are only provided as examples, and some of the functions and operations may be optional, combined into fewer functions and operations, or expanded into additional functions and operations without detracting from the essence of the disclosed embodiments. In some embodiments, the method 600 may include additional blocks or fewer blocks.

FIG. 7 is a flow diagram showing another example portion of a method 700 for analyzing behavior of a particle system, in accordance with some embodiments of the present disclosure. The method may be carried out via a simulation system, such as but not limited to the simulation system 110 of FIG. 1.

The method 700, at block B702, includes grouping particles for calculations. For example, particles may be grouped such that calculations for the particles, such as distance calculations between particles, may be performed in overlapping time periods, such as at the same time. In these and other embodiments, the calculations for each of the particles in the group may be performed by a thread of a multi-thread processing unit. In some embodiments, a size for each of the groups may be consistent, such that each group includes the same number of particles. In these and other embodiments, the size for each of the groups may be a multiple of two. Alternately or additionally, particles may be grouped together that are in the same cell.

At block B704, it may be determined if all particles are part of a particle group. For example if each group includes the same number of particles and the number of particles is not equally divisible by the number of particles in a group, some particles may not be part of a group. Note that particles may not be grouped with particles that are not part of the same cell such that particles are only grouped with particles from the same cell. In response to some particles not being part of a group, the method 700 may proceed to B706. In response to all particles being part of a group, the method 700 may proceed to block 708.

At block B706, particle groups may be formed with one or more placeholder particles. A particle group formed with placeholder particles may include remaining particles that are not part of a group and one or more of the placeholder particles so that the particle group includes the same number of particles as other particle groups.

In some embodiments, the placeholder particles may be given a location in the particle system such that a distance determined at block B712 between each of the placeholder particles and other particles is larger than the interaction distance. As a result, the distances between the placeholder particles and other particles may be calculated, but no interactions between the placeholder particles and other particles may be considered by the simulation. Thus, including the placeholder particles in groups may not affect the behavior of the particle system as determined by the simulation.

As an example, as described with respect to FIG. 5, distances between particles from a primary cell may be determined with respect to particles from thirteen cells adjacent to the primary cell. The thirteen cells may be referred to calculation cells. However, distances between particles from the primary cell may not be determined with respect to particles from thirteen other cells adjacent to the primary cell based on those distances having previously been calculated. The thirteen other cells may be referred to non-calculation cells. Note that distances between the particles of the calculation cells are not determined. Rather, the calculations are related to determining the distances between the particles of the primary cell and the particles of the calculation cells.

In some embodiments, the groups of particles may be a group from the primary cell or groups from the calculation cells. When the group of particles is from the primary cell, the distances between the placeholder particles within the group may be calculated. As a result, each of the placeholder particles may be located at vertices of non-calculation cells that are at least a cell edge length away from the primary cell and the calculation cells. As a result, the distance between the placeholder particles from the group from the primary cell may be more than the interaction distance from any other particle in the primary cell and any other particle from the calculation cells.

When the group of particles is from a calculation cell, the distances between the placeholder particles within the group may not be calculated. As a result, the placeholder particles may all be located in a single location that is at least the interaction distance away from the primary cell and any placeholder particles from a group from the primary cell. What is more, all placeholder particles from groups of particles from calculation cells may be located in the same location because no distances between these particles is determined. Arranging the placeholder particles in this or a similar manner may allow all calculations of groups of particles to be performed in a similar manner which may assist reduce a processing time for the calculations.

At block B708, stored position values of the particles from the groups may be accessed from memory. The stored position values may be accessed in the third value type. The stored position values may be accessed when a distance between particles is calculated during a simulation.

At block B710, the position values of the particles in the adjacent cells may be adjusted based on the local coordinate systems of the adjacent cells. In these and other embodiments, cell offsets based on the distances between the given cell and the adjacent cells may also be accessed. The cell offsets may be accessed in the third value type. The cell offsets may be applied to the position values of the particles in the adjacent cells to obtain the locations of the particles in the adjacent cells in the local coordinate system of the given cell.

At block B712, distances between particles in the group and other particles may be determined based on the position values of the particles in the third value type. In some embodiments, the other particles may also be in one or more groups. For example, a processing unit may be configured to perform a process that determines distances between particles in a group from a primary cell and particles in multiple groups from one or more calculation cells. In these and other embodiments, differences between the position values in the third value type may be calculated to determine the distances.

At block B714, the distances between the particles in the group and the other particles may be converted to the second value type. After converting the distances between particles, the scalar value applied to both the position values of the particles and the cell offsets may be removed. For example, an inverse of the scalar value may be applied to the distances between particles.

Modifications, additions, or omissions may be made to the method 700 without departing from the scope of the present disclosure. For example, the functions and/or operations performed may be implemented in differing order. Furthermore, the outlined functions and operations are only provided as examples, and some of the functions and operations may be optional, combined into fewer functions and operations, or expanded into additional functions and operations without detracting from the essence of the disclosed embodiments. In some embodiments, the method 700 may include additional blocks or fewer blocks.

For example, in some embodiments, the method 700 may include comparing the distances to the interaction distance. In response to a distance being less than or equal to the interaction distance, an interaction between particles from which the distance results may be considered by the simulation. In these and other embodiments, the interaction may be a nonbonded interaction that may be based on the distance. In response to a distance being more than the interaction distance, no interaction between the particles from which the distance results may be considered by the simulation.

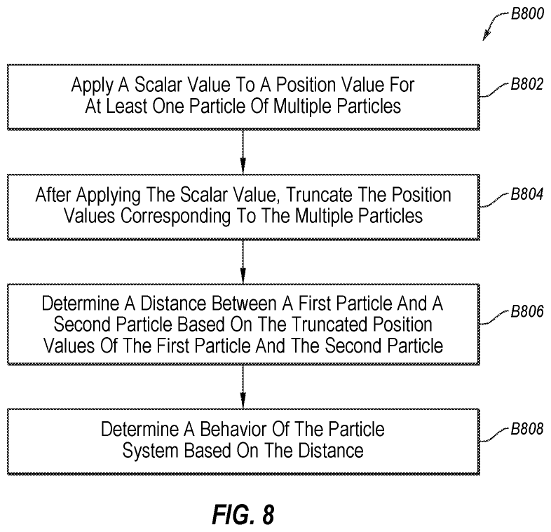

FIG. 8 is a flow diagram showing another example method 800 for analyzing behavior of a particle system, in accordance with some embodiments of the present disclosure. The method may be carried out via a simulation system, such as but not limited to the simulation system 110 of FIG. 1.

The method 800, at block B802, includes applying a scalar value to a position value for at least one particle of multiple particles. In some embodiments, the multiple particles may be part of a particle system. In these and other embodiments, the scalar value may be applied during an analysis of the behavior of the multiple particles. In some embodiments, the scalar value may be based on one or more parameters for the analysis.

At block B804, after applying the scalar value, the position values corresponding to the multiple particles are truncated. At block B806, a distance between a first particle and a second particle is determined based on the truncated position values of the first particle and the second particle. At block B808, a behavior of the particle system is determined based on the distance.

Modifications, additions, or omissions may be made to the method 800 without departing from the scope of the present disclosure. For example, the functions and/or operations performed may be implemented in differing order. Furthermore, the outlined functions and operations are only provided as examples, and some of the functions and operations may be optional, combined into fewer functions and operations, or expanded into additional functions and operations without detracting from the essence of the disclosed embodiments. In some embodiments, the method 800 may include additional blocks or fewer blocks.

For example, in some embodiments, the method 800 may include calculating interactions between the first particle and the second particle using the distance between the first particle and the second particle. In these and other embodiments, the behavior of the particle system may be determined based on the calculated interactions.

In some embodiments, the method 800 may further include partitioning the particle system into multiple cells. In these and other embodiments, each cell of the multiple cells may include a dimension and encompass one or more of the particles. In these and other embodiments, the scalar value may be further based on the dimension of the cells.

Alternately or additionally, the method 800 may further include translating a global position value for each of the particles from a global coordinate system to a local cell coordinate system based on the cells that include the particles. In these and other embodiments, the position value that is truncated may be the position value of the cells in the local cell coordinate system. In some embodiments, the dimension of the cells may be based on a distance at which interactions between particles are not considered during the determining the behavior of the particle system.

Alternately or additionally, the method 800 may further include storing the truncated position value for each of the particles and before determining the distance, removing the scalar value applied to the truncated position value such that the distance between the first particle and the second particle are determined using the truncated position value with the scalar value removed. In these and other embodiments, the method 800 may further include after removing the scalar value applied to the truncated position value, changing a value type of the truncated position value such that the distance between the first particle and the second particle are determined using the truncated position value with the scalar value removed and value type changed.

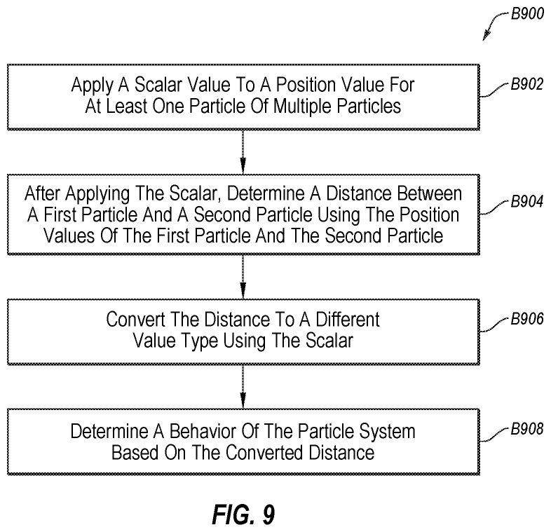

FIG. 9 is a flow diagram showing another example method 900 for analyzing behavior of a particle system, in accordance with some embodiments of the present disclosure. The method may be carried out via a simulation system, such as but not limited to the simulation system 110 of FIG. 1.

The method 900, at block B902, includes applying a scalar value to a position value for at least one particle of multiple particles. In some embodiments, the multiple particles may be part of a particle system. In these and other embodiments, the scalar value may be applied during an analysis of the behavior of the multiple particles. In some embodiments, the scalar value may be based on one or more parameters for the analysis.

At block B904, after applying the scalar value, a distance is determined between a first particle of the particles and a second particle of the particles using the position values of the first particle and the second particle. At block B906, the distance is converted from a first value type to a different value type using the scalar value. At block B908, a behavior of the particle system is determined based on the converted distance.

Modifications, additions, or omissions may be made to the method 900 without departing from the scope of the present disclosure. For example, the functions and/or operations performed may be implemented in differing order. Furthermore, the outlined functions and operations are only provided as examples, and some of the functions and operations may be optional, combined into fewer functions and operations, or expanded into additional functions and operations without detracting from the essence of the disclosed embodiments. In some embodiments, the method 900 may include additional blocks or fewer blocks.

For example, in some embodiments, the method 900 may include grouping the particles into multiple groups of equal size and after applying the scalar value, determining, for a first group, a distance between one or more particles of the particles of the first group and one or more particles of second particles of the particle system using the position values of the particles of the first group and the second particles. In these and other embodiments, the first particle may be part of the first group and the second particle may be part of the second particles.

Alternately or additionally, the method 900 may further include generating an additional group for particles not grouped into the multiple groups. In these and other embodiments, the generating may include providing one or more placeholder particles in the additional group when determining distances between one or more particles of the additional group and one or more other particles. In these and other embodiments, the placeholder particles may be positioned in the particle system such that no interactions are calculated between the placeholder particles and the particles of the particle system.

Alternately or additionally, the method 900 may further include calculating one or more interactions between the first particle and the second particle using the distance between the first particle and the second particle. In these and other embodiments, the behavior of the particle system may be determined based on the one or more calculated interactions.

Alternately or additionally, the method 900 may further include after applying the scalar value, truncating the position values of the particles such that the truncated position values of the first particle and the second particle are used to determine the distance between the first particle and the second particle.

Alternately or additionally, the method 900 may further include partitioning the particle system into multiple cells. In these and other embodiments, at least one cell may include a dimension and encompass one or more of the particles. In some embodiments, the scalar value may be further based on the dimension of the cells. In some embodiments, the dimension of the cells may be based on a distance at which interactions between particles are not considered during the determining the behavior of the particle system.

### EXAMPLE COMPUTING DEVICE

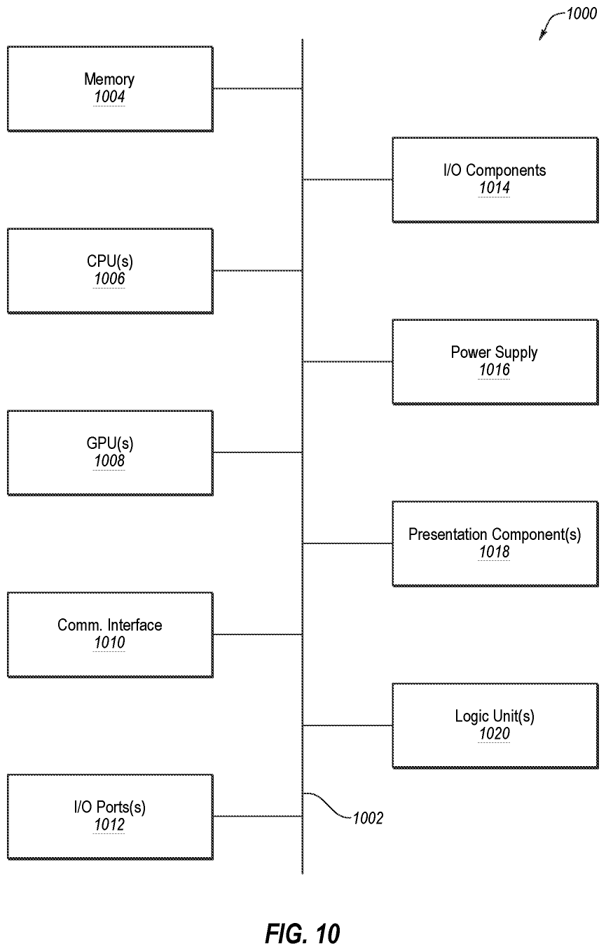

FIG. 10 is a block diagram of an example computing device(s) 1000 suitable for use in implementing some embodiments of the present disclosure. Computing device 1000 may include an interconnect system 1002 that directly or indirectly couples the following devices: memory 1004, one or more central processing units (CPUs) 1006, one or more graphics processing units (GPUs) 1008, a communication interface 1010, I/O ports 1012, input/output components 1014, a power supply 1016, one or more presentation components 1018 (e.g., display(s)), and one or more logic units 1020.

Although the various blocks of FIG. 10 are shown as connected via the interconnect system 1002 with lines, this is not intended to be limiting and is for clarity only. For example, in some embodiments, a presentation component 1018, such as a display device, may be considered an I/O component 1014 (e.g., if the display is a touch screen). As another example, the CPUs 1006 and/or GPUs 1008 may include memory (e.g., the memory 1004 may be representative of a storage device in addition to the memory of the GPUs 1008, the CPUs 1006, and/or other components). In other words, the computing device of FIG. 10 is merely illustrative. Distinction is not made between such categories as “workstation,” “server,” “laptop,” “desktop,” “tablet,” “client device,” “mobile device,” “hand-held device,” “game console,” “electronic control unit (ECU),” “virtual reality system,” “augmented reality system,” and/or other device or system types, as all are contemplated within the scope of the computing device of FIG. 10.

The interconnect system 1002 may represent one or more links or busses, such as an address bus, a data bus, a control bus, or a combination thereof. The interconnect system 1002 may include one or more bus or link types, such as an industry standard architecture (ISA) bus, an extended industry standard architecture (EISA) bus, a video electronics standards association (VESA) bus, a peripheral component interconnect (PCI) bus, a peripheral component interconnect express (PCIe) bus, and/or another type of bus or link. In some embodiments, there are direct connections between components. As an example, the CPU 1006 may be directly connected to the memory 1004. Further, the CPU 1006 may be directly connected to the GPU 1008. Where there is direct, or point-to-point, connection between components, the interconnect system 1002 may include a PCIe link to carry out the connection. In these examples, a PCI bus need not be included in the computing device 1000.

The memory 1004 may include any of a variety of computer-readable media. The computer-readable media may be any available media that may be accessed by the computing device 1000. The computer-readable media may include both volatile and nonvolatile media, and removable and non-removable media. By way of example, and not limitation, the computer-readable media may comprise computer-storage media and communication media.

The computer-storage media may include both volatile and nonvolatile media and/or removable and non-removable media implemented in any method or technology for storage of information such as computer-readable instructions, data structures, program modules, and/or other data types. For example, the memory 1004 may store computer-readable instructions (e.g., that represent a program(s) and/or a program element(s), such as an operating system. Computer-storage media may include, but is not limited to, RAM, ROM, EEPROM, flash memory or other memory technology, CD-ROM, digital versatile disks (DVD) or other optical disk storage, magnetic cassettes, magnetic tape, magnetic disk storage or other magnetic storage devices, or any other medium that may be used to store the desired information and that may be accessed by computing device 1000. As used herein, computer storage media does not comprise signals per se.

The computer storage media may embody computer-readable instructions, data structures, program modules, and/or other data types in a modulated data signal such as a carrier wave or other transport mechanism and includes any information delivery media. The term “modulated data signal” may refer to a signal that has one or more of its characteristics set or changed in such a manner as to encode information in the signal. By way of example, and not limitation, the computer storage media may include wired media such as a wired network or direct-wired connection, and wireless media such as acoustic, RF, infrared and other wireless media. Combinations of any of the above should also be included within the scope of computer-readable media.

The CPU(s) 1006 may be configured to execute at least some of the computer-readable instructions to control one or more components of the computing device 1000 to perform one or more of the methods and/or processes described herein. The CPU(s) 1006 may each include one or more cores (e.g., one, two, four, eight, twenty-eight, seventy-two, etc.) that are capable of handling a multitude of software threads simultaneously. The CPU(s) 1006 may include any type of processor, and may include different types of processors depending on the type of computing device 1000 implemented (e.g., processors with fewer cores for mobile devices and processors with more cores for servers). For example, depending on the type of computing device 1000, the processor may be an Advanced RISC Machines (ARM) processor implemented using Reduced Instruction Set Computing (RISC) or an ×86 processor implemented using Complex Instruction Set Computing (CISC). The computing device 1000 may include one or more CPUs 1006 in addition to one or more microprocessors or supplementary co-processors, such as math co-processors.

In addition to or alternatively from the CPU(s) 1006, the GPU(s) 1008 may be configured to execute at least some of the computer-readable instructions to control one or more components of the computing device 1000 to perform one or more of the methods and/or processes described herein. One or more of the GPU(s) 1008 may be an integrated GPU (e.g., with one or more of the CPU(s) 1006 and/or one or more of the GPU(s) 1008 may be a discrete GPU. In embodiments, one or more of the GPU(s) 1008 may be a coprocessor of one or more of the CPU(s) 1006. The GPU(s) 1008 may be used by the computing device 1000 to render graphics (e.g., 3D graphics) or perform general purpose computations. For example, the GPU(s) 1008 may be used for General-Purpose computing on GPUs (GPGPU). The GPU(s) 1008 may include hundreds or thousands of cores that are capable of handling hundreds or thousands of software threads simultaneously. The GPU(s) 1008 may generate pixel data for output images in response to rendering commands (e.g., rendering commands from the CPU(s) 1006 received via a host interface). The GPU(s) 1008 may include graphics memory, such as display memory, for storing pixel data or any other suitable data, such as GPGPU data. The display memory may be included as part of the memory 1004. The GPU(s) 1008 may include two or more GPUs operating in parallel (e.g., via a link). The link may directly connect the GPUs (e.g., using NVLINK) or may connect the GPUs through a switch (e.g., using NVSwitch). When combined together, each GPU 1008 may generate pixel data or GPGPU data for different portions of an output or for different outputs (e.g., a first GPU for a first image and a second GPU for a second image). Each GPU may include its own memory, or may share memory with other GPUs.

In addition to or alternatively from the CPU(s) 1006 and/or the GPU(s) 1008, the logic unit(s) 1020 may be configured to execute at least some of the computer-readable instructions to control one or more components of the computing device 1000 to perform one or more of the methods and/or processes described herein. In embodiments, the CPU(s) 1006, the GPU(s) 1008, and/or the logic unit(s) 1020 may discretely or jointly perform any combination of the methods, processes and/or portions thereof. One or more of the logic units 1020 may be part of and/or integrated in one or more of the CPU(s) 1006 and/or the GPU(s) 1008 and/or one or more of the logic units 1020 may be discrete components or otherwise external to the CPU(s) 1006 and/or the GPU(s) 1008. In embodiments, one or more of the logic units 1020 may be a coprocessor of one or more of the CPU(s) 1006 and/or one or more of the GPU(s) 1008.

Examples of the logic unit(s) 1020 include one or more processing cores and/or components thereof, such as Tensor Cores (TCs), Tensor Processing Units(TPUs), Pixel Visual Cores (PVCs), Vision Processing Units (VPUs), Graphics Processing Clusters (GPCs), Texture Processing Clusters (TPCs), Streaming Multiprocessors (SMs), Tree Traversal Units (TTUs), Artificial Intelligence Accelerators (AIAs), Deep Learning Accelerators (DLAs), Arithmetic-Logic Units (ALUs), Application-Specific Integrated Circuits (ASICs), Floating Point Units (FPUs), I/O elements, peripheral component interconnect (PCI) or peripheral component interconnect express (PCIe) elements, and/or the like.

The communication interface 1010 may include one or more receivers, transmitters, and/or transceivers that enable the computing device 1000 to communicate with other computing devices via an electronic communication network, including wired and/or wireless communications. The communication interface 1010 may include components and functionality to enable communication over any of a number of different networks, such as wireless networks (e.g., Wi-Fi, Z-Wave, Bluetooth, Bluetooth LE, ZigBee, etc.), wired networks (e.g., communicating over Ethernet or InfiniBand), low-power wide-area networks (e.g., LoRaWAN, SigFox, etc.), and/or the Internet.

The I/O ports 1012 may enable the computing device 1000 to be logically coupled to other devices including the I/O components 1014, the presentation component(s) 1018, and/or other components, some of which may be built into (e.g., integrated in) the computing device 1000. Illustrative I/O components 1014 include a microphone, mouse, keyboard, joystick, game pad, game controller, satellite dish, scanner, printer, wireless device, etc. The I/O components 1014 may provide a natural user interface (NUI) that processes air gestures, voice, or other physiological inputs generated by a user. In some instances, inputs may be transmitted to an appropriate network element for further processing. An NUI may implement any combination of speech recognition, stylus recognition, facial recognition, biometric recognition, gesture recognition both on screen and adjacent to the screen, air gestures, head and eye tracking, and touch recognition (as described in more detail below) associated with a display of the computing device 1000. The computing device 1000 may include depth cameras, such as stereoscopic camera systems, infrared camera systems, RGB camera systems, touchscreen technology, and combinations of these, for gesture detection and recognition. Additionally, the computing device 1000 may include accelerometers or gyroscopes (e.g., as part of an inertia measurement unit (IMU)) that enable detection of motion. In some examples, the output of the accelerometers or gyroscopes may be used by the computing device 1000 to render immersive augmented reality or virtual reality.

The power supply 1016 may include a hard-wired power supply, a battery power supply, or a combination thereof. The power supply 1016 may provide power to the computing device 1000 to enable the components of the computing device 1000 to operate.

The presentation component(s) 1018 may include a display (e.g., a monitor, a touch screen, a television screen, a heads-up-display (HUD), other display types, or a combination thereof), speakers, and/or other presentation components. The presentation component(s) 1018 may receive data from other components (e.g., the GPU(s) 1008, the CPU(s) 1006, etc.), and output the data (e.g., as an image, video, sound, etc.).

### EXAMPLE DATA CENTER

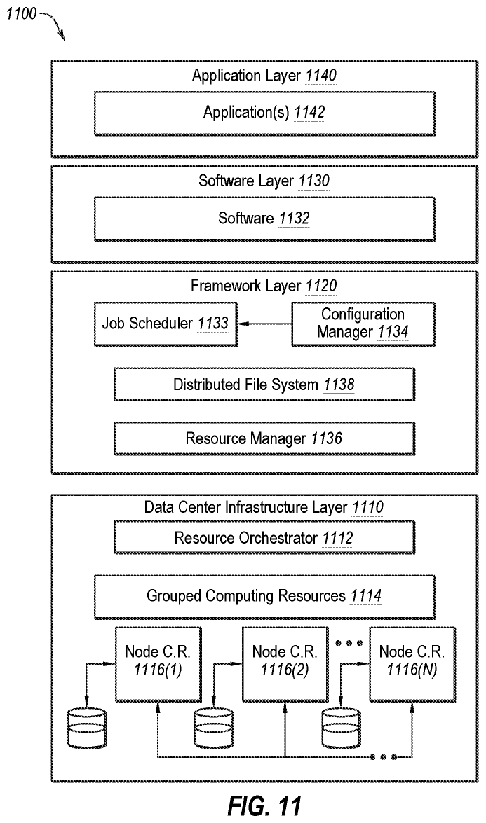

FIG. 11 illustrates an example data center 1100 that may be used in at least one embodiments of the present disclosure. The data center 1100 may include a data center infrastructure layer 1110, a framework layer 1120, a software layer 1130, and/or an application layer 1140.

As shown in FIG. 11, the data center infrastructure layer 1110 may include a resource orchestrator 1112, grouped computing resources 1114, and node computing resources (“node C.R.s”) 1116(1)-1116(N), where “N” represents any whole, positive integer. In at least one embodiment, node C.R.s 1116(1)-1116(N) may include, but are not limited to, any number of central processing units (CPUs) or other processors (including DPUs, accelerators, field programmable gate arrays (FPGAs), graphics processors or graphics processing units (GPUs), etc.), memory devices (e.g., dynamic read-only memory), storage devices (e.g., solid state or disk drives), network input/output (NW I/O) devices, network switches, virtual machines (VMs), power modules, and/or cooling modules, etc. In some embodiments, one or more node C.R.s from among node C.R.s 1116(1)-1116(N) may correspond to a server having one or more of the above-mentioned computing resources. In addition, in some embodiments, the node C.R.s 1116(1)-1161(N) may include one or more virtual components, such as vGPUs, vCPUs, and/or the like, and/or one or more of the node C.R.s 1116(1)-1116(N) may correspond to a virtual machine (VM).

In at least one embodiment, grouped computing resources 1114 may include separate groupings of node C.R.s 1116 housed within one or more racks (not shown), or many racks housed in data centers at various geographical locations (also not shown). Separate groupings of node C.R.s 1116 within grouped computing resources 1114 may include grouped compute, network, memory or storage resources that may be configured or allocated to support one or more workloads. In at least one embodiment, several node C.R.s 1116 including CPUs, GPUs, DPUs, and/or other processors may be grouped within one or more racks to provide compute resources to support one or more workloads. The one or more racks may also include any number of power modules, cooling modules, and/or network switches, in any combination.

The resource orchestrator 1112 may configure or otherwise control one or more node C.R.s 1116(1)-1116(N) and/or grouped computing resources 1114. In at least one embodiment, resource orchestrator 1112 may include a software design infrastructure (SDI) management entity for the data center 1100. The resource orchestrator 1112 may include hardware, software, or some combination thereof.

In at least one embodiment, as shown in FIG. 11, framework layer 1120 may include a job scheduler 1133, a configuration manager 1134, a resource manager 1136, and/or a distributed file system 1138. The framework layer 1120 may include a framework to support software 1132 of software layer 1130 and/or one or more application(s) 1142 of application layer 1140. The software 1132 or application(s) 1142 may respectively include web-based service software or applications, such as those provided by Amazon Web Services, Google Cloud and Microsoft Azure. The framework layer 1120 may be, but is not limited to, a type of free and open-source software web application framework such as Apache Spark™ (hereinafter “Spark”) that may utilize distributed file system 1138 for large-scale data processing (e.g., “big data”). In at least one embodiment, job scheduler 1133 may include a Spark driver to facilitate scheduling of workloads supported by various layers of data center 1100. The configuration manager 1134 may be capable of configuring different layers such as software layer 1130 and framework layer 1120 including Spark and distributed file system 1138 for supporting large-scale data processing. The resource manager 1136 may be capable of managing clustered or grouped computing resources mapped to or allocated for support of distributed file system 1138 and job scheduler 1133. In at least one embodiment, clustered or grouped computing resources may include grouped computing resource 1114 at data center infrastructure layer 1110. The resource manager 1136 may coordinate with resource orchestrator 1112 to manage these mapped or allocated computing resources.

In at least one embodiment, software 1132 included in software layer 1130 may include software used by at least portions of node C.R.s 1116(1)-1116(N), grouped computing resources 1114, and/or distributed file system 1138 of framework layer 1120. One or more types of software may include, but are not limited to, Internet web page search software, e-mail virus scan software, database software, and streaming video content software.

In at least one embodiment, application(s) 1142 included in application layer 1140 may include one or more types of applications used by at least portions of node C.R.s 1116(1)-1116(N), grouped computing resources 1114, and/or distributed file system 1138 of framework layer 1120. One or more types of applications may include, but are not limited to, any number of a genomics application, a cognitive compute, and a machine learning application, including training or inferencing software, machine learning framework software (e.g., PyTorch, TensorFlow, Caffe, etc.), and/or other machine learning applications used in conjunction with one or more embodiments.

In at least one embodiment, any of configuration manager 1134, resource manager 1136, and resource orchestrator 1112 may implement any number and type of self-modifying actions based on any amount and type of data acquired in any technically feasible fashion. Self-modifying actions may relieve a data center operator of data center 1100 from making possibly bad configuration decisions and possibly avoiding underutilized and/or poor performing portions of a data center.

The data center 1100 may include tools, services, software or other resources to train one or more machine learning models or predict or infer information using one or more machine learning models according to one or more embodiments described herein. For example, a machine learning model(s) may be trained by calculating weight parameters according to a neural network architecture using software and/or computing resources described above with respect to the data center 1100. In at least one embodiment, trained or deployed machine learning models corresponding to one or more neural networks may be used to infer or predict information using resources described above with respect to the data center 1100 by using weight parameters calculated through one or more training techniques, such as but not limited to those described herein.

In at least one embodiment, the data center 1100 may use CPUs, application-specific integrated circuits (ASICs), GPUs, FPGAs, and/or other hardware (or virtual compute resources corresponding thereto) to perform training and/or inferencing using above-described resources. Moreover, one or more software and/or hardware resources described above may be configured as a service to allow users to train or performing inferencing of information, such as image recognition, speech recognition, or other artificial intelligence services.

### EXAMPLE NETWORK ENVIRONMENTS

Network environments suitable for use in implementing embodiments of the disclosure may include one or more client devices, servers, network attached storage (NAS), other backend devices, and/or other device types. The client devices, servers, and/or other device types (e.g., each device) may be implemented on one or more instances of the computing device(s) 1000 of FIG. 10—e.g., each device may include similar components, features, and/or functionality of the computing device(s) 1000. In addition, where backend devices (e.g., servers, NAS, etc.) are implemented, the backend devices may be included as part of a data center 1100, an example of which is described in more detail herein with respect to FIG. 11.

Components of a network environment may communicate with each other via a network(s), which may be wired, wireless, or both. The network may include multiple networks, or a network of networks. By way of example, the network may include one or more Wide Area Networks (WANs), one or more Local Area Networks (LANs), one or more public networks such as the Internet and/or a public switched telephone network (PSTN), and/or one or more private networks. Where the network includes a wireless telecommunications network, components such as a base station, a communications tower, or even access points (as well as other components) may provide wireless connectivity.

Compatible network environments may include one or more peer-to-peer network environments—in which case a server may not be included in a network environment—and one or more client-server network environments—in which case one or more servers may be included in a network environment. In peer-to-peer network environments, functionality described herein with respect to a server(s) may be implemented on any number of client devices.

In at least one embodiment, a network environment may include one or more cloud-based network environments, a distributed computing environment, a combination thereof, etc. A cloud-based network environment may include a framework layer, a job scheduler, a resource manager, and a distributed file system implemented on one or more of servers, which may include one or more core network servers and/or edge servers. A framework layer may include a framework to support software of a software layer and/or one or more application(s) of an application layer. The software or application(s) may respectively include web-based service software or applications. In embodiments, one or more of the client devices may use the web-based service software or applications (e.g., by accessing the service software and/or applications via one or more application programming interfaces (APIs)). The framework layer may be, but is not limited to, a type of free and open-source software web application framework such as that may use a distributed file system for large-scale data processing (e.g., “big data”).

A cloud-based network environment may provide cloud computing and/or cloud storage that carries out any combination of computing and/or data storage functions described herein (or one or more portions thereof). Any of these various functions may be distributed over multiple locations from central or core servers (e.g., of one or more data centers that may be distributed across a state, a region, a country, the globe, etc.). If a connection to a user (e.g., a client device) is relatively close to an edge server(s), a core server(s) may designate at least a portion of the functionality to the edge server(s). A cloud-based network environment may be private (e.g., limited to a single organization), may be public (e.g., available to many organizations), and/or a combination thereof (e.g., a hybrid cloud environment).

The client device(s) may include at least some of the components, features, and functionality of the example computing device(s) 1000 described herein with respect to FIG. 10. By way of example and not limitation, a client device may be embodied as a Personal Computer (PC), a laptop computer, a mobile device, a smartphone, a tablet computer, a smart watch, a wearable computer, a Personal Digital Assistant (PDA), an MP3 player, a virtual reality headset, a Global Positioning System (GPS) or device, a video player, a video camera, a surveillance device or system, a vehicle, a boat, a flying vessel, a virtual machine, a drone, a robot, a handheld communications device, a hospital device, a gaming device or system, an entertainment system, a vehicle computer system, an embedded system controller, a remote control, an appliance, a consumer electronic device, a workstation, an edge device, any combination of these delineated devices, or any other suitable device.

The subject technology of the present invention is illustrated, for example, according to various aspects described below. Various examples of aspects of the subject technology are described as numbered examples (1, 2, 3, etc.) for convenience. These are provided as examples and do not limit the subject technology. The aspects of the various implementations described herein may be omitted, substituted for aspects of other implementations, or combined with aspects of other implementations unless context dictates otherwise. For example, one or more aspects of example 1 below may be omitted, substituted for one or more aspects of another example (e.g., example 2) or examples, or combined with aspects of another example . The following is a non-limiting summary of some example implementations presented herein.

Example 1 may include a system including one or more processing units to perform operation. The operations may include partitioning a particle system that includes multiple particles into multiple cells. In some embodiments, each cell of the multiple cells may include a dimension and encompassing one or more of the multiple particles and applying a scalar value, based on the dimension, to a position value for each of the multiple particles. The operations may further include after applying the scalar value, truncating the position values of the multiple particles, determining a distance between a first particle of the multiple particles and a second particle of the multiple particles based on the truncated position value of the first particle and the truncated position value of the second particle, and analyzing a behavior of the particle system based on the distance.

Example 2 may include a method of particle system analysis. The method may include during an analysis of behavior of multiple particles in a particle system, applying a scalar value, based on parameters for the analysis, to a position value for each of the multiple particles and after applying the scalar value, truncating the position values of the multiple particles. The method may further include determining a distance between a first particle of the multiple particles and a second particle of the multiple particles based on the truncated position values of the first particle and the second particle and determining a behavior of the particle system based on the distance.

Example 3 may include a method of particle system analysis. The method may include during an analysis of behavior of multiple particles in a particle system, applying a scalar value, based on parameters for the analysis, to a position value for each of the multiple particles and after applying the scalar value, truncating the position values of the multiple particles. The method may further include after truncating the position values, converting the position values to a different value type using the scalar value; after converting the position values, determining a distance between a first particle of the multiple particles and a second particle of the multiple particles based on the truncated position values of the different value type of the first particle and the second particle; and determining a behavior of the particle system based on the distance.

Example 4 may include a system including one or more processing units to perform operations. The operations may include partitioning a particle system that includes multiple particles into multiple cells, each cell of the multiple cells including a dimension and encompassing one or more of the multiple particles and applying a scalar value, based on the dimension, to a position value for each of the multiple particles. The operations may further include after applying the scalar value, determining a distance between a first particle of the multiple particles and a second particle of the multiple particles using the position values of the first particle and the second particle and converting the distance to a different value type using the scalar value. The operations may further include analyzing a behavior of the particle system based on the distance.

Example 5 may include method including during an analysis of behavior of multiple particles in a particle system, applying a scalar value, based on parameters for the analysis, to a position value for each of the multiple particles and after applying the scalar value, determining a distance between a first particle of the multiple particles and a second particle of the multiple particles using the position values of the first particle and the second particle. The method may further include converting the distance to a different value type using the scalar value and determining a behavior of the particle system based on the converted distance.

Example 6 may include a method that includes during an analysis of behavior of multiple particles in a particle system, applying a scalar value, based on parameters for the analysis, to a position value for each of the multiple particles and grouping the multiple particles into multiple groups of equal size. The method may further include after applying the scalar value, determining, for a first group of the multiple particles, a distance between each of first multiple particles of the first group and each of multiple second particles of the multiple particles using the position values of the first multiple particles and the second multiple particles. The method may further include converting the distances to a different value type using the scalar value and determining a behavior of the particle system based on the converted distances.

The disclosure may be described in the general context of computer code or machine-useable instructions, including computer-executable instructions such as program modules, being executed by a computer or other machine, such as a personal data assistant or other handheld device. Generally, program modules including routines, programs, objects, components, data structures, etc., refer to code that perform particular tasks or implement particular abstract data types. The disclosure may be practiced in a variety of system configurations, including hand-held devices, consumer electronics, general-purpose computers, more specialty computing devices, etc. The disclosure may also be practiced in distributed computing environments where tasks are performed by remote-processing devices that are linked through a communications network.

As used herein, a recitation of “and/or” with respect to two or more elements should be interpreted to mean only one element, or a combination of elements. For example, “element A, element B, and/or element C” may include only element A, only element B, only element C, element A and element B, element A and element C, element B and element C, or elements A, B, and C. In addition, “at least one of element A or element B” may include at least one of element A, at least one of element B, or at least one of element A and at least one of element B. Further, “at least one of element A and element B” may include at least one of element A, at least one of element B, or at least one of element A and at least one of element B. Additionally, “one or more of A, B, and C, etc.” may be construed in a similar manner.

Additionally, the use of the terms “first,” “second,” “third,” etc., are not necessarily used herein to connote a specific order or number of elements. Generally, the terms “first,” “second,” “third,” etc., are used to distinguish between different elements as generic identifiers. Absence a showing that the terms “first,” “second,” “third,” etc., connote a specific order, these terms should not be understood to connote a specific order. Furthermore, absence a showing that the terms first,” “second,” “third,” etc., connote a specific number of elements, these terms should not be understood to connote a specific number of elements. For example, a first widget may be described as having a first side and a second widget may be described as having a second side. The use of the term “second side” with respect to the second widget may be to distinguish such side of the second widget from the “first side” of the first widget and not to connote that the second widget has two sides.

Additionally, if a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to embodiments containing only one such recitation, even when the same claim includes the introductory phrases “one or more” or “at least one” and indefinite articles such as “a” or “an” (e.g., “a” and/or “an” should be interpreted to mean “at least one” or “one or more”); the same holds true for the use of definite articles used to introduce claim recitations. Additionally, use of the term “based on” should not be interpreted as “only based on” or “based only on.” Rather, a first element being “based on” a second element includes instances in which the first element is based on the second element but may also be based on one or more additional elements.

The subject matter of the present disclosure is described with specificity herein to meet statutory requirements. However, the description itself is not intended to limit the scope of this disclosure. Rather, the inventors have contemplated that the claimed subject matter might also be embodied in other ways, to include different steps or combinations of steps similar to the ones described in this document, in conjunction with other present or future technologies. Moreover, although the terms “step” and/or “block” may be used herein to connote different elements of methods employed, the terms should not be interpreted as implying any particular order among or between various steps herein disclosed unless and except when the order of individual steps is explicitly described.

What is claimed is:

1. A system comprising:
one or more processing units to perform operations, the operations comprising:
partitioning a plurality of particles into a plurality of cells, one or more cells of the plurality of cells including a dimension and encompassing one or more of the plurality of particles;
applying a scalar value, based on the dimension, to a position value for each of the plurality of particles;
after applying the scalar value, determining a distance between a first particle of the plurality of particles and a second particle of the plurality of particles using the position values of the first particle and the second particle;
converting the distance from a first value type to a different value type using the scalar value; and
analyzing a behavior of the particle system based on the distance.

2. The system of claim 1, wherein the operations further comprise:
grouping the plurality of particles into a plurality of groups of equal size; and
after applying the scalar value, determining, for a first group of the plurality of particles, a distance between at least one particle of a first plurality of particles of the first group and at least one particle of a plurality of second particles of the plurality of particles using position values corresponding to the first plurality of particles and the second plurality of particles, wherein the first particle is part of the first group and the second particle is part of the plurality of second particles.

3. The system of claim 1, wherein the operations further comprise generating an additional group of particles that includes particles not grouped into the plurality of groups, the generating including providing one or more placeholder particles in the additional group to determine one or more distances between one or more particles of the additional group and one or more other particles of the plurality of particles, wherein the placeholder particles are positioned in the particle system such that no interactions are calculated between the placeholder particles and the particles of the particle system.

4. The system of claim 1, wherein the operations further comprise translating a global position value for at least one particle of the plurality of particles from a global coordinate system to a local cell coordinate system based on the cells of the plurality of cells that include the plurality of particles, wherein the position value to which the scalar value is applied is the position value of the cells in the local cell coordinate system.

5. The system of claim 1, wherein the operations further comprise, after applying the scalar, truncating the position values of the plurality of particles such that the truncated position values of the first particle and the second particle are used to determine the distance between the first particle and the second particle.

6. The system of claim 1, wherein the dimension is based on a distance at which one or more interactions between particles are not considered during the analyzing the behavior of the particle system.

7. The system of claim 1, wherein the operations further comprise calculating one or more interactions between the first particle and the second particle using the distance between the first particle and the second particle, wherein the behavior of the particle system is determined based on the calculated interactions.

8. A method comprising:
during an analysis of behavior of a plurality of particles in a particle system, applying a scalar value, based on one or more parameters for the analysis, to a position value for one or more particles of the plurality of particles;
determining, after applying the scalar value, a distance between a first particle of the plurality of particles and a second particle of the plurality of particles using the position values of the first particle and the second particle;
converting the distance from a first value type to a different value type using the scalar value; and
determining a behavior of the particle system based on the converted distance.

9. The method of claim 8, further comprising:
grouping the plurality of particles into a plurality of groups of equal size; and
determining, after applying the scalar value, for a first group of the plurality of particles, a distance between one or more particles of a first plurality of particles of the first group and one or more particles of a plurality of second particles of the plurality of particles using the position values of the first plurality of particles and the second plurality of particles, wherein the first particle is part of the first group and the second particle is part of the plurality of second particles.

10. The method of claim 9, further comprising generating an additional group for particles not grouped into the plurality of groups, the generating including providing one or more placeholder particles in the additional group to determine distances between particles of the additional group and one or more other particles of the plurality of particles, wherein the placeholder particles are positioned in the particle system such that no interactions are calculated between the placeholder particles and the particles of the particle system.

11. The method of claim 8, further comprising calculating one or more interactions between the first particle and the second particle using the distance between the first particle and the second particle, wherein the behavior of the particle system is determined based on the calculated interactions.

12. The method of claim 8, further comprising after applying the scalar value, truncating the position values of the plurality of particles such that the truncated position values of the first particle and the second particle are used to determine the distance between the first particle and the second particle.

13. The method of claim 8, further comprising partitioning the particle system into a plurality of cells, at least one cell of the plurality of cells including a dimension and encompassing one or more of the plurality of particles, wherein the scalar value is further based on the dimension of the cells.

14. The method of claim 13, wherein the dimension is based on a distance at which interactions between particles are not considered during the determining the behavior of the particle system.

15. A method comprising:
applying, during an analysis of behavior of a plurality of particles, a scalar value based on one or more parameters for the analysis, to a position value for each of the plurality of particles;
grouping the plurality of particles into a plurality of groups of equal size;
determining, after applying the scalar value, a distance between at least one particle of a first group of particles of the plurality of particles and at least one particle of a second group of particles of the plurality of particles using the position values of the first group of particles and the second group of particles;
converting the distances from a first value type to a different value type using the scalar value; and
determining a behavior of the particle system based on the converted distances.

16. The method of claim 15, further comprising:
generating an additional group for particles not grouped into either the first or second groups of particles, the generating including providing one or more placeholder particles in the additional group for the step of determining distances between particles of the additional group and one or more other particles of the plurality of particles.

17. The method of claim 16, wherein the placeholder particles are positioned in the particle system such that no interactions are calculated between the placeholder particles and other particles of the particle system.

18. The method of claim 15, further comprising truncating, after applying the scalar value, the position values of the plurality of particles such that the truncated position values of the first group of particles and the second group of particles are used to determine one or more distances between the first group of particles and the second group of particles.

19. The method of claim 15, further comprising partitioning the particle system into a plurality of cells, at least one cell of the plurality of cells including a dimension and encompassing one or more of the plurality of particles, wherein the scalar value is further based on the dimension of the cells and the particles of a particular group of the first or second groups of particles all being encompassed in one cell of the plurality of cells.

20. The method of claim 19, wherein the dimension is based on a distance at which one or more interactions between particles are not considered during the determining the behavior of the particle system.
